(19) United States
(12) Patent Application Publication
(10) Pub. No.: US 2019/0237991 A1
(43) Pub. Date: Aug. 1, 2019

(54) POWER GENERATION, STORAGE AND DISTRIBUTION SYSTEM

(71) Applicant: Roberto Carlos Baldizon Diaz, Miami, FL (US)

(72) Inventor: Roberto Carlos Baldizon Diaz, Miami, FL (US)

(21) Appl. No.: 16/257,296

(22) Filed: Jan. 25, 2019

Related U.S. Application Data
(60) Provisional application No. 62/622,325, filed on Jan. 26, 2018.

(51) Int. Cl. H02J 7/35; H02J 7/04; H02S 40/38; H02S 40/32; H02J 7/00; H02J 3/38; G01R 31/36

(52) U.S. Cl. CPC H02J 7/355; H02J 7/04; H02S 40/38; H02S 40/32; H01M 10/465; H02J 7/0047; H02J 3/383; G01R 31/3646; H02J 7/0063

(57) ABSTRACT

A power generation system which consist of a plug and play all-built-in easy install and use system. The system includes solar panels, racks, and an all-built-in power box with auxiliary AC input capabilities, and communication capabilities communicated to the internet that allow for a plurality of uses for the electricity generated with such device. The power box is composed of a charge controller which charges a plurality of batteries. The batteries are connected to an inverter which outputs 110 V & 220 V electricity. All the components except the solar panels, other auxiliary energy generating systems such as generators, and other installation components, such as the solar panels' racks are encapsulated inside a metal box.

### CROSS-REFERENCE TO RELATED APPLICATION

This application claims the benefit of priority of U.S. provisional application No. 62/622,325, filed Jan. 26, 2018, the contents of which are herein incorporated by reference.

### BACKGROUND OF THE INVENTION

The present invention relates to power generation and distribution, and more particularly to a self-contained hybrid (grid-tied and off-grid) electrical power generation and distribution system which accepts multiple AC inputs and can be used for a variety of purposes such as backup, emergency, off-grid living, as a pay as you go energy service for customers which have systems with the software installed in their hardware and would like to prepay their energy usage instead of their system, energy independent living for customers who want more control on their energy supply locally or remotely, utility auxiliary service, peak shaving, direct consumption, net metering, efficiently adjusting energy consumption and production to time of use rates and customer behaviors, among others.

Current power plants and distributed energy generation systems typically require a larger project scope or a complex system installation in order to work.

As can be seen, there is a need for a self-contained system that is pre-configured with all the cables, accessories, and ports that enable it to be simply installed by anyone without previous electrical knowledge or training providing all modern benefits of distributed energy sources to build a more reliable & smarter grid.

### SUMMARY OF THE INVENTION

In one aspect of the present invention, a power generation, storage and distribution system is disclosed. The system includes a housing having a cover, a front panel, and a back panel. A central control unit that controls a charging circuit, a storage circuit, and a distribution circuit are each carried within the housing. The charging circuit is configured to receive an AC line input. The AC line input is provided as an input to rectifier. A charging control is interposed between the rectifier and a storage battery. The storage circuit has a charge controller configured to receive a voltage input from an electrical power generator and produce an output to the battery. The distribution circuit includes an inverter that is operatively connected to the storage circuit. A transformer is interposed between the inverter and an AC outlet that is carried on one of the front panel or the back panel.

The power generation, storage, and distribution system may also include a voltage regulator that is also carried within the housing. The voltage regulator is configured to provide a regulated source of DC power to one or more outlets carried on one of the front panel or the back panel. In some embodiments, an indication and display unit is operatively connected to the central control unit. A plurality of indicators on one of the front panel or the back panel, show an operational state of each of the charging circuit, the storage circuit, and the distribution circuit.

In other embodiments, a display panel is provided on one of the front panel or the back panel. The display provides indications regarding an operational state of one or more of the charging circuit, the storage circuit, and the distribution circuit.

In yet other embodiments, the power generation, storage, and distribution system also includes a communications module configured to provide communications between the system and a computer, server, or platform, software or program via a network.

In a preferred embodiment, the electrical power generator is a solar panel array. In yet other embodiments, one or more battery modules, each carried in a discrete housing, contain one or more additional batteries. One or more cables connect the one or more battery modules to the power generation, storage, and distribution system. The one or more battery modules may each be provisioned with a display panel configured to provide a charging state of the one or more additional batteries contained within the battery module. The housing and the discrete housing are configured to be stacked upon each other.

In yet other embodiments, the AC outlet is adapted to be connected to a power distribution grid.

These and other features, aspects and advantages of the present invention will become better understood with reference to the following drawings, description and claims.

### BRIEF DESCRIPTION OF THE DRAWINGS

FIG. 1 is a perspective view of a possible configuration for the power generation, storage and distribution system shown in use.

FIG. 2 is a front elevation view of a possible configuration for the power generation, storage and distribution system.

FIG. 3 is a side elevation view of a possible configuration for the power generation, storage and distribution system.

FIG. 4 is a rear elevation view of a possible configuration for the power generation, storage and distribution system.

FIG. 5 is a front perspective view of a storage component shown with a possible configuration for the power generation, storage and distribution system.

FIG. 6 is a rear perspective view of the storage component shown with a possible configuration for the power generation, storage and distribution system.

FIG. 7 is an alternative embodiment of a possible configuration for the power generation, storage and distribution system.

FIG. 8 is a flowchart illustrating the power generation, storage and distribution system operation.

FIG. 9 is a circuit diagram for the power generation, storage and distribution system.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, embodiments of the of the power generation, storage and distribution system of the present invention provide an emergency backup energy source and for otherwise generating, storing and distributing electrical energy into a power grid or circuit for consumption. Embodiments may include auxiliary grid services, when needed, by utilizing switches connected to the internet, and software, servers, or other platforms, by a communication system that allows for greater user control and product flexibility.

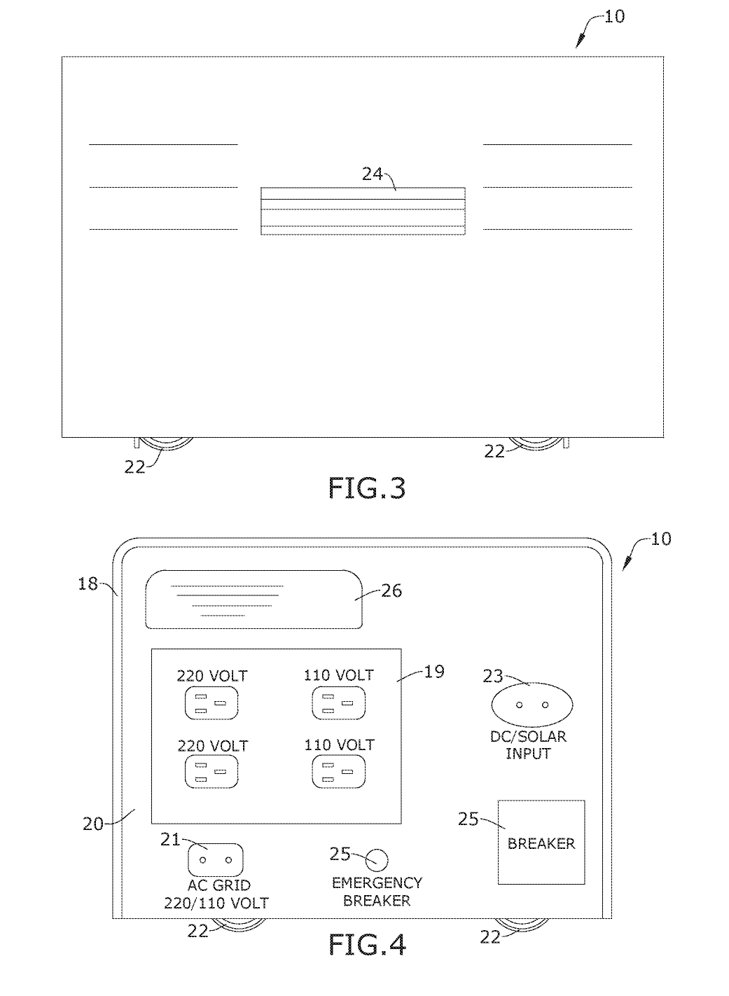

As seen in reference to the drawings of FIGS. 1-7, the of the power generation, storage and distribution system 10 may be connected to one or more solar panels 12, or distributed energy source, or a local grid connection, which supply DC or AC electricity. The DC or AC power is then used to charge one or more batteries or fuel cells carried within a power generator module 18. The stored energy may then be utilized to power one or more appliances 14, 16 or other electrically powered items by a direct connection or connection to a local electrical circuit.

The power generation, storage and distribution system 10 is contained within a housing cover 18 and a front panel 20. The system may be configured in stationary or moveable embodiments. A plurality of casters, or ground wheels 22 may be provided in moveable variants, with the ground wheels 22 selected based on the terrain and/or floor conditions in which it is deployed. One or more handles 24 may also be provided for transport of the housing. The housing may be sealed and environmentally insulated for placement in austere conditions.

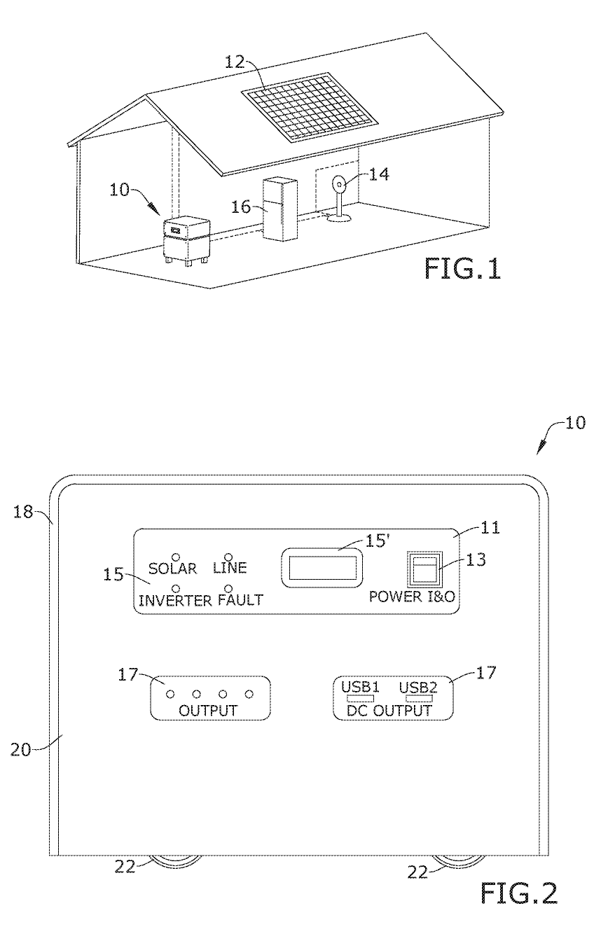

A front panel 20 of the system may carry a control and status panel 11, such as shown in FIG. 2. The control and status panel may have a power button 13 and one or more status indicator lights or displays 15. The power button 13 activates a central control unit 47. The displays 15 may include a status indicator for the solar panel 12 operational status, such as, a line indicator, an inverter indicator, and a fault indicator. A production and charge state meter may also be provided. Likewise, one or more output power indicators 15 may be provided to show that the system 10 is storing or otherwise distributing power. One or more convenience outlets 17 may also be provided on the front panel, such as a universal serial bus (USB), or other desired DC power output connection for powering equipment while servicing or utilizing the system 10.

A rear panel 20, as shown in reference to FIG. 4 may include a plurality of input and output connections. An inverter 45 is carried within the housing to convert the solar DC energy to AC power. One or more AC outlets 19 may be provided to connect an AC powered device directly to the unit 10. Likewise, an AC grid connection 21 may be provided to couple the system for distribution of AC power as an input to a power grid. The rear panel may also include an input connection 21 for the solar grid 12. One or more circuit breakers 25 are provided to protect the system 10. The housing may include one or more vents 26 and optional cooling fans to dissipate heat produced during the generation, storage, or distribution of power by the unit 10.

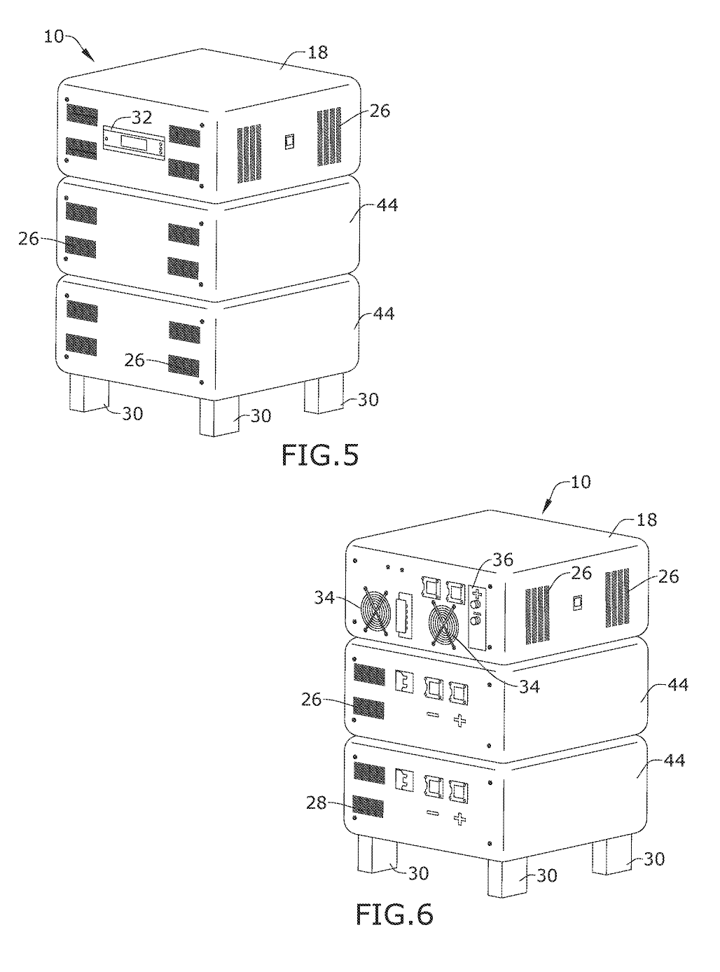

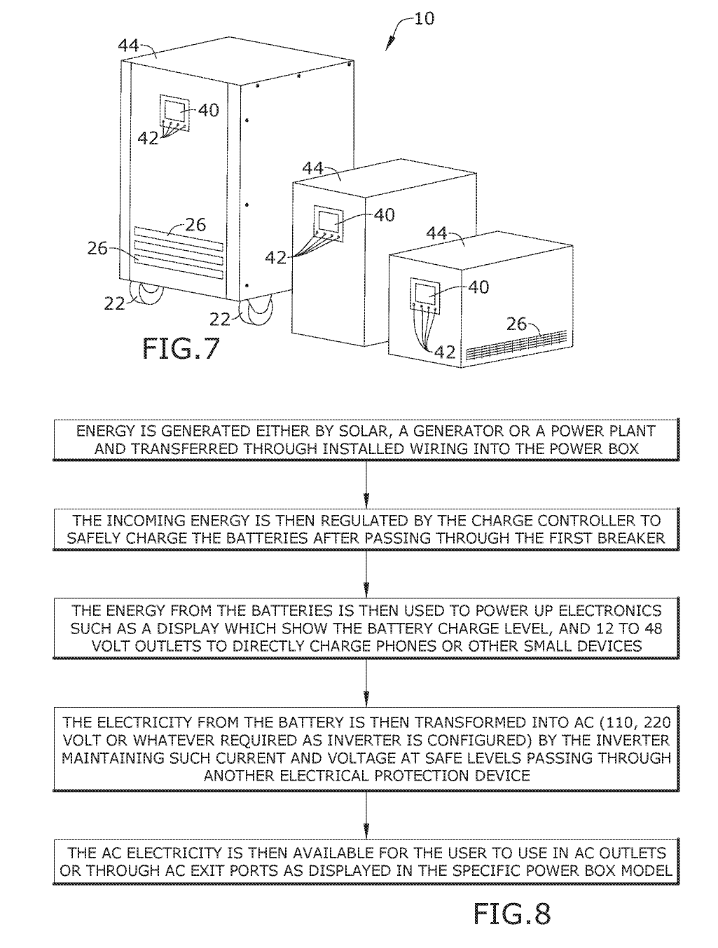

The DC energy produced by the solar panel 12 may be stored within one or more batteries 41. A battery 41 may be carried within the base unit 10. Additional storage capacity may be provided by one or more battery modules 44. The battery modules 44 may be provided in a stacked configuration, such as shown in FIGS. 5 and 6. They may also be provided in a distributed configuration, such as shown in reference to FIG. 7. The batteries 41 could be of any chemistry chosen to best meet local system requirements. Instead of batteries 41 the system 10 could have fuel cells in place to serve as energy storage devices.

The battery storage modules 44 include a charge controller 43, which is also carried within the generator module 10. As previously indicated, the stored electricity from the batteries 41 may then be converted to 110 V, 220 V, or a desired voltage level by an inverter 45 so that people can use their traditional home appliances with it by direct connection to the system or connection of the system to the building's power distribution panel. The system 10 may also include an AC input 49 for charging the batteries 41. The AC input is processed by a rectifier 50 and a charging control 51, with an overvoltage protection may be provided between the rectifier 50 and the batteries 41. A display panel 40 may be provided on the battery storage module 44. One or more control buttons 42 may also be included, such as for specifying an output voltage, checking a charge status, and the like.

The system 10 is configured to provide a plug and play, all in one solution for an electrical power supply or electrical grid input that has all the required systems for a Distributed Energy Generation and Storage solution already built in, which allows for other auxiliary power so that the system 10 is reliable and can power up more devices and circuits using the same pre-wired embodiment.

The system 10 comes with all the cables and ports that enable it to be simply installed by anyone without previous electrical knowledge or experience. The device 10 may also be configured with sensors and communication devices for input of solar or other distributed energy generated power into the smart power grid, once the power generation module has attained a fully charged capacity to provide not just storage, but also frequency regulation and aid with electricity for peak generation.

The system 10 may also include a communication module 52, to permit connection to a computer network. The system 10 may then be controlled or monitored remotely. The communication capabilities of the system 10 connect it to the internet to manage and operate remotely, as well as report usage, production, and status of the system 10. This capability allows for greater use when connecting it to an energy load management software and platforms, which maximize returns and user benefits.

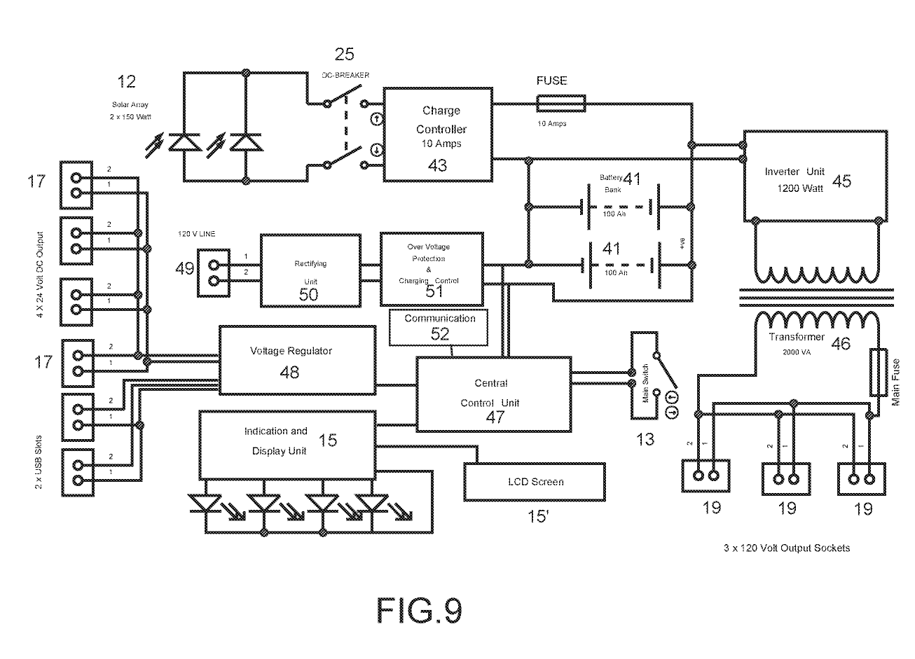

The system 10 may include or be connected to one or more solar panels 10 configured to generate solar power, as well as any other source of electrical energy, like a diesel powered generator, or a small wind turbine, or the local electrical grid, among others. As shown in the non-limiting embodiment shown in the circuit diagram of FIG. 9, the power generation module is configured to include the charge controller 43, batteries 41 and an inverter 45 to develop AC power output via a transformer 46 to the one or more outlets 19. The kit may also include a plurality of cables to connect to solar panels 12 or other electrical energy generating devices and, in certain embodiments, to connect with the power distribution grid. As will be appreciated, while described in the context as a solar power generation, any other distributed energy generation source of DC power input may be connected to the DC input connection 23.

The inverter 45 can be of a capacity and quantity, depending on the AC power requirements of the user. Likewise, the battery capacity can be configured with different size and different capacity or chemistry based on an anticipated power needs of the operator by the addition of one or more battery modules 44 or fuel cells. The charge controller 43 can be selected to handle higher capacity of batteries 41 and/or quantity of battery modules 44.

With the simplified system, anyone would be able to install the system 10 in case of emergency or to gain independence from the utility power grid. The system 10 can be used to provide direct DC electricity and/or an AC power source. Other usage ranges are contemplated, such as: for commercial and residential electricity usage; for emergency and power bill reduction; as well as revenue generation. Revenue generation may include: providing grid auxiliary services, shifting demand use based on time of use, helping regulate frequency. It may also include integration with novel business models, such as platforms connected to smart sensors and local electrical behavior to optimize energy use, production, and consumption. They may also include pay as you go systems which would allow customers to pay only for the energy they consume instead of buying a system, etc.

It should be understood, of course, that the foregoing relates to exemplary embodiments of the invention and that modifications may be made without departing from the spirit and scope of the invention as set forth in the following claims.

What is claimed is:

1. A power generation, storage and distribution system, comprising:
a housing having a cover, a front panel, and a back panel;
a central control unit controlling a charging circuit, a storage circuit, and a distribution circuit each carried within the housing;
the charging circuit configured to receive an AC line input, a rectifier and a charging control interposed between the rectifier and a storage battery;
the storage circuit having a charge controller configured to receive a voltage input from an electrical power generator and produce an output to the battery; and
the distribution circuit having an inverter operatively connected to the storage circuit and a transformer interposed between the inverter and an AC outlet carried on one of the front panel or the back panel.

2. The power generation, storage, and distribution system of claim 1, further comprising:
a voltage regulator, carried within the housing, the voltage regulator configured to provide a regulated source of DC power to one or more outlets carried on one of the front panel or the back panel.

3. The power generation, storage, and distribution system of claim 2, further comprising:
an indication and display unit operatively connected to the central control unit, and a plurality of indicators on one of the front panel or the back panel, the plurality of indicators showing an operational state of each of the charging circuit, the storage circuit, and the distribution circuit.

4. The power generation, storage, and distribution system of claim 3, further comprising:
a display panel on one of the front panel or the back panel, the display providing indicia regarding an operational state of one or more of the charging circuit, the storage circuit, and the distribution circuit.

5. The power generation, storage, and distribution system of claim 4, further comprising:
a communications module configured to provide communications between the power generation, storage, and distribution system and a computer via a computer network to work in conjunction with sensors, circuits, and other internet connected devices to optimize the local energy behavior. This would also allow for grid ancillary services, and other novel business solutions such as enabling customers to pay only for energy they will use instead of buying a system through software.

6. The power generation, storage, and distribution system of claim 1, wherein the electrical power generator is a solar panel array or any other distributed energy generating device, or the local grid as needed.

7. The power generation, storage, and distribution system of claim 1, further comprising:
one or more battery or fuel cell modules each carried in a discrete housing containing one or more additional batteries; and
one or more cables connecting the one or more battery or fuel cell modules to the power generation, storage, and distribution system.

8. The power generation, storage, and distribution system of claim 7, further comprising:
a display panel configured to provide a charging state of the one or more additional batteries contained within the battery or fuel cell module.

9. The power generation, storage, and distribution system of claim 8, wherein the housing and the discrete housing are configured to be stacked upon each other.

10. The power generation, storage, and distribution system of claim 1, wherein the AC outlet is adapted to be connected to a power distribution grid.
